(19) United States
(12) Patent Application Publication
(10) Pub. No.: US 2024/0264428 A1
(43) Pub. Date: Aug. 8, 2024

(54) MIRROR DEVICE

(71) Applicant: Hamamatsu Photonics K.K., Hamamatsu-shi (JP)

(72) Inventors: Tomoyuki IDE, Hamamatsu-shi (JP); Daiki SUZUKI, Hamamatsu-shi (JP)

(73) Assignee: Hamamatsu Photonics K.K., Hamamatsu-shi (JP)

(21) Appl. No.: 18/432,299

(22) Filed: Feb. 5, 2024

(30) Foreign Application Priority Data
Feb. 7, 2023 (JP) 2023-016818

(51) Int. Cl. G02B 26/08; G02B 26/10

(52) U.S. Cl. CPC G02B 26/0816; G02B 26/101

(57) ABSTRACT

A mirror device includes a support portion; a first movable portion including a body portion including a first surface and a second surface opposite to the first surface, a mirror surface being formed on the first surface and a rib portion being formed on the second surface; and a first torsion bar that couples the first movable portion to the support portion such that the first movable portion is swingable around an X-axis. The rib portion includes a first extending portion extending along an outer edge of the body portion when viewed in a direction perpendicular to the second surface. The first extending portion includes a protrusion portion protruding outward from the outer edge of the body portion and extending along the outer edge of the body portion when viewed in the direction perpendicular to the second surface.

### TECHNICAL FIELD

One aspect of the present disclosure relates to a mirror device.

### BACKGROUND

For example, Japanese Unexamined Patent Publication No. 2004-325578 describes a deflection mirror in which a movable portion having a mirror surface is swingably coupled to a support portion. In the deflection mirror described in Patent Literature 1, in order to reduce distortion of the mirror surface during driving, a rib is formed on a back surface of the movable portion.

In the mirror device described above, effectively suppressing distortion of the mirror surface or facilitating manufacturing is required.

### SUMMARY

Therefore, an object of one aspect of the present disclosure is to provide a mirror device capable of effectively suppressing distortion of a mirror surface and facilitating manufacturing.

[1] According to one aspect of the present disclosure, there is provided a mirror device including: “a support portion; a movable portion including a body portion including a first surface and a second surface opposite to the first surface, a mirror surface being formed on the first surface and a rib portion being formed on the second surface; and a coupling portion that couples the movable portion to the support portion such that the movable portion is swingable around a predetermined axis.

The rib portion includes an extending portion extending along an outer edge of the body portion when viewed in a direction perpendicular to the second surface. The extending portion includes a protrusion portion protruding outward from the outer edge of the body portion and extending along the outer edge of the body portion when viewed in the direction perpendicular to the second surface.”

In the mirror device, the rib portion includes the extending portion extending along the outer edge of the body portion when viewed in the direction perpendicular to the second surface. Accordingly, the rigidity of the body portion at the outer edge portion at which distortion is likely to occur can be increased, and distortion of the body portion (in other words, distortion of the mirror surface) can be effectively suppressed. On the other hand, from the viewpoint of effectively suppressing distortion of the body portion, it is preferable that the rib portion is formed close to the outer edge of the body portion; however, for example, when the extending portion is formed such that the side surface of the extending portion is flush with the side surface of the body portion (such that the side surface of the extending portion coincides with the side surface of the body portion when viewed in the direction perpendicular to the second surface), it is concerned that the devices in which the extending portion protrudes from the outer edge of the body portion and the devices in which the extending portion does not protrude from the outer edge of the body portion coexist due to manufacturing errors (for example, etching errors). In this case, for example, it may be difficult to set manufacturing conditions in a post-process. In this regard, in the mirror device, the extending portion includes the protrusion portion protruding outward (side opposite to the body portion) from the outer edge of the body portion and extending along the outer edge of the body portion when viewed in the direction perpendicular to the second surface. Accordingly, the occurrence of such a situation can be avoided, and manufacturing can be facilitated. Therefore, according to the mirror device, distortion of the mirror surface can be effectively suppressed, and manufacturing can be facilitated.

[2] In the mirror device according to one aspect of the present disclosure, according to [1], “when a direction parallel to the axis is a first direction, and a direction perpendicular to both the first direction and the direction perpendicular to the second surface is a second direction, a length of the protrusion portion along the outer edge of the body portion may be larger than a minimum width of the coupling portion in the second direction.” In this case, distortion of the body portion can be more effectively suppressed.

[3] In the mirror device according to one aspect of the present disclosure, according to [1] or [2], “when a direction parallel to the axis is a first direction, and a direction perpendicular to both the first direction and the direction perpendicular to the second surface is a second direction, a protrusion length of the protrusion portion from the outer edge of the body portion may be smaller than a minimum width of the coupling portion in the second direction.” In this case, the downsizing of the mirror device can be achieved while suppressing distortion of the body portion.

[4] In the mirror device according to one aspect of the present disclosure, according to any one of [1] to [3], “when viewed in the direction perpendicular to the second surface, the rib portion may include a pair of first portions extending from a side of a reference position toward one side in a predetermined direction and facing each other in a direction perpendicular to the predetermined direction, a first connecting portion connected to the pair of first portions, a pair of second portions extending from the side of the reference position toward the other side in the predetermined direction and facing each other in the direction perpendicular to the predetermined direction, and a second connecting portion connected to the pair of second portions. The extending portion may be formed of the first connecting portion and the second connecting portion.” In this case, while distortion of the entirety of the body portion can be suppressed by the first portions and the second portions, distortion of the outer edge portion of the body portion can be suppressed by the first connecting portion and the second connecting portion.

[5] In the mirror device according to one aspect of the present disclosure, according to [4], “a width of the first connecting portion may be wider than a width of each of the pair of first portions, and a width of the second connecting portion may be wider than a width of each of the pair of second portions.” In this case, the rigidity of the body portion at the outer edge portion at which distortion is likely to occur can be increased, and distortion of the body portion can be more effectively suppressed.

[6] In the mirror device according to one aspect of the present disclosure, according to [4] or [5], “the pair of first portions may be connected to each other on the side of the reference position, and the pair of second portions may be connected to each other on the side of the reference position.” In this case, the rigidity of the rib portion can be increased, and damage to the rib portion or the peeling of the rib portion can be suppressed.

[7] In the mirror device according to one aspect of the present disclosure, according to [6], “when viewed in the direction perpendicular to the second surface, inner edges of the pair of first portions may be smoothly connected to each other, and inner edges of the pair of second portions may be smoothly connected to each other.” In this case, damage to the rib portion or the peeling of the rib portion can be further suppressed.

[8] In the mirror device according to one aspect of the present disclosure, according to any one of [4] to [7], “the reference position may coincide with a center of the body portion when viewed in the direction perpendicular to the second surface.” In this case, the rib portion can be disposed on the body portion in a well-balanced manner, and distortion of the body portion can be more effectively suppressed.

[9] In the mirror device according to one aspect of the present disclosure, according to any one of [4] to [8], “when viewed in the direction perpendicular to the second surface, the rib portion may further include a pair of third portions extending from the side of the reference position toward one side in the direction perpendicular to the predetermined direction and facing each other in the predetermined direction, and a pair of fourth portions extending from the side of the reference position toward the other side in the direction perpendicular to the predetermined direction and facing each other in the predetermined direction.” In this case, distortion of the body portion can be more effectively suppressed.

[10] In the mirror device according to one aspect of the present disclosure, according to [9], “when viewed in the direction perpendicular to the second surface, an angle between the pair of first portions may be larger than an angle between the pair of third portions.” In this case, the length of the first connecting portion connected to the pair of first portions can be lengthened, and distortion of the body portion can be more effectively suppressed.

[11] In the mirror device according to one aspect of the present disclosure, according to any one of [1] to [10], “the movable portion may further include a ring-shaped portion surrounding the body portion with a gap interposed between the ring-shaped portion and the body portion when viewed in the direction perpendicular to the second surface, and connected to the coupling portion, and a connection portion that connects the ring-shaped portion to the body portion. At least a part of the protrusion portion may overlap the gap when viewed in the direction perpendicular to the second surface.” In this case, the body portion is connected to the coupling portion via the ring-shaped portion, the occurrence that stress generated in the coupling portion during swinging of the movable portion is directly transmitted to the body portion can be suppressed, and dynamic distortion of the body portion can be suppressed.

[12] In the mirror device according to one aspect of the present disclosure, according to [11], “the protrusion portion may not overlap the ring-shaped portion when viewed in the direction perpendicular to the second surface.” In this case, the occurrence that stress generated in the coupling portion during swinging of the movable portion is transmitted to the body portion can be suppressed, and dynamic distortion of the body portion can be suppressed. In addition, the occurrence that stress generated in the ring-shaped portion is transmitted to the body portion via the rib portion can be suppressed, and distortion (static distortion) of the body portion can be suppressed.

[13] In the mirror device according to one aspect of the present disclosure, according to [11], “a part of the protrusion portion may overlap the ring-shaped portion when viewed in the direction perpendicular to the second surface.” In this case, for example, the rib portion may be connected to both the body portion and the ring-shaped portion, so that the strength of the rib portion can be improved.

[14] In the mirror device according to one aspect of the present disclosure, according to any one of [11] to [13], “the movable portion may include a pair of the connection portions. When a direction parallel to the axis is a first direction, and a direction perpendicular to both the first direction and the direction perpendicular to the second surface is a second direction, the pair of connection portions may be disposed on one side and the other side in the second direction with respect to the body portion, respectively. The rib portion may include a pair of first portions extending from a side of a reference position toward one side in the first direction and facing each other in the second direction, a first connecting portion connected to the pair of first portions, a pair of second portions extending from the side of the reference position toward the other side in the first direction and facing each other in the second direction, and a second connecting portion connected to the pair of second portions. The extending portion may be formed of the first connecting portion and the second connecting portion.” In this case, by disposing the pair of connection portions on the one side and the other side in the second direction with respect to the body portion, respectively, the pair of connection portions can be disposed at positions away from the coupling portion, and the occurrence that stress generated in the coupling portion during swinging of the movable portion is transmitted to the body portion can be further suppressed. In addition, by forming the rib portion so as to include the first portions, the first connecting portion, the second portions, and the second connecting portion, distortion of the body portion can be suppressed while suppressing an increase in the moment of inertia of the movable portion around the axis.

[15] In the mirror device according to one aspect of the present disclosure, according to any one of [11] to [14], “the protrusion portion may protrude outward from the outer edge of the body portion at least on the axis. When a direction parallel to the axis is a first direction, and a direction perpendicular to both the first direction and the direction perpendicular to the second surface is a second direction, a distance between the protrusion portion and the ring-shaped portion on the axis may be smaller than a minimum width of the coupling portion in the second direction.” In this case, the downsizing of the mirror device can be achieved.

[16] In the mirror device according to one aspect of the present disclosure, according to [14], “the first connecting portion and the second connecting portion may extend to intersect the axis when viewed in the direction perpendicular to the second surface.” Static distortion is likely to occur at a position far from the pair of connection portions (for example, a position on the axis); however, according to the mirror device, distortion of the body portion at this position can be effectively suppressed. In addition, the moment of inertia of the movable portion can be reduced compared to a case where the first connecting portion and the second connecting portion are disposed at positions away from the axis.

[17] In the mirror device according to one aspect of the present disclosure, according to or [16], “the rib portion may further include a pair of third portions extending from the side of the reference position toward the one side in the second direction and facing each other in the first direction, and a pair of fourth portions extending from the side of the reference position toward the other side in the second direction and facing each other in the first direction.” Stress generated in the coupling portion during swinging of the movable portion is likely to be transmitted to positions close to the pair of connection portions, and dynamic distortion is likely to occur at these positions; however, according to the mirror device, distortion of the body portion at these position can be effectively suppressed.

[18] In the mirror device according to one aspect of the present disclosure, according to [14], [16], or [17], “the pair of first portions may be connected to each other on the side of the reference position, and the pair of second portions may be connected to each other on the side of the reference position.” In this case, the rigidity of the rib portion can be increased, and damage to the rib portion or the peeling of the rib portion can be suppressed.

[19] In the mirror device according to one aspect of the present disclosure, according to any one of [14] and [16] to [18], “the reference position may coincide with a center of the body portion when viewed in the direction perpendicular to the second surface.” In this case, the rib portion can be disposed on the body portion in a well-balanced manner, and distortion of the body portion can be more effectively suppressed.

[20] In the mirror device according to one aspect of the present disclosure, according to any one of [1] to [19], “the protrusion portion may not be in contact with portions other than the body portion.” In this case, the transmission of stress from the portions other than the body portion to the body portion via the rib portion can be suppressed. In addition, the size of the rib portion can be reduced, and an increase in the moment of inertia of the movable portion can be suppressed.

[21] In the mirror device according to one aspect of the present disclosure, according to any one of [1] to [20], “the support portion, the movable portion, and the coupling portion may be formed by a semiconductor substrate including a first semiconductor layer, a second semiconductor layer, and an insulating layer disposed between the first semiconductor layer and the second semiconductor layer. The body portion may be formed by at least the first semiconductor layer. The rib portion may be by from at least the second semiconductor layer.” In the mirror device as well, the above-described actions and effects such as being able to effectively suppress distortion of the mirror surface and being able to facilitate manufacturing can be achieved. In addition, for example, compared to a case where the support portion, the movable portion, and the coupling portion are formed as separate members and joined to each other, the strength of the device can be improved.

According to one aspect of the present disclosure, it is possible to provide the mirror device capable of effectively suppressing distortion of the mirror surface and facilitating manufacturing.

### BRIEF DESCRIPTION OF THE DRAWINGS

FIG. 1 is a plan view of a mirror device according to an embodiment.

FIG. 2 is a bottom view of the mirror device.

FIG. 3 is a partial enlarged view of FIG. 2.

FIG. 4 is a cross-sectional view taken along line IV-IV in FIG. 3.

FIG. 5 is a perspective view of a peripheral portion of a first movable portion.

FIG. 6 is a partial enlarged view of FIG. 3.

### DETAILED DESCRIPTION

Hereinafter, an embodiment of the present disclosure will be described in detail with reference to the drawings. In the following description, the same reference signs are used for the same or equivalent elements, and duplicate descriptions will be omitted.

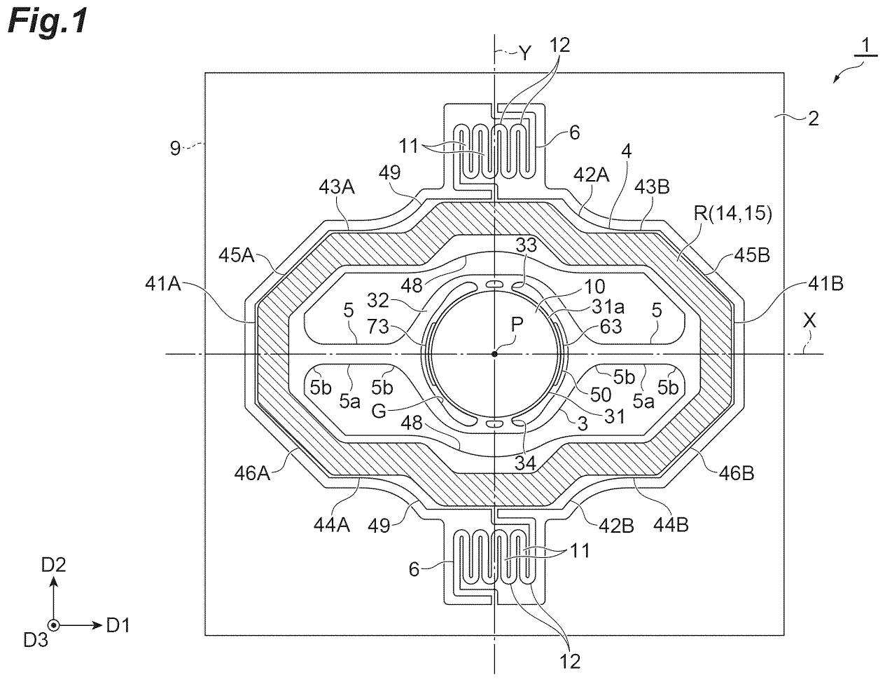

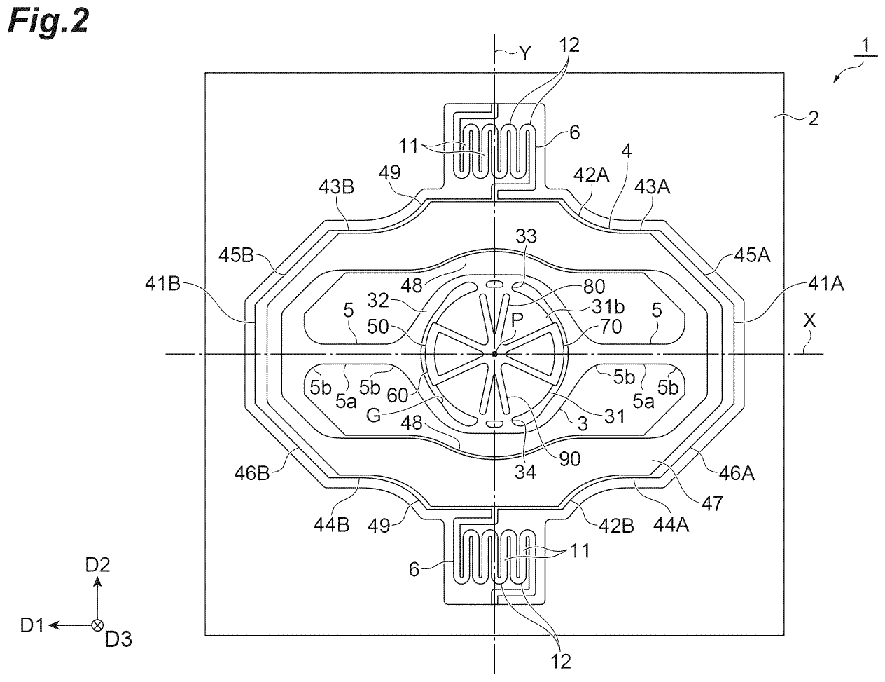

As shown in FIGS. 1 to 4, a mirror device 1 includes a support portion 2, a first movable portion 3, a second movable portion 4, a pair of first torsion bars (first coupling portions) 5, a pair of second torsion bars (second coupling portions) 6, and a magnetic field generation portion 9. In the mirror device 1, the first movable portion 3 having a mirror surface 10 swings around each of an X-axis (first axis) and a Y-axis (second axis perpendicular to the first axis) orthogonal to each other. The mirror device 1 can be used, for example, in an optical switch for optical communication, an optical scanner, and the like. In the following description, a direction parallel to the X-axis is a direction D1 (first direction), a direction parallel to the Y-axis is a direction D2 (second direction), and a direction perpendicular to both the direction D1 and the direction D2 is a direction D3 (third direction). Incidentally, in FIG. 2, the illustration of the magnetic field generation portion 9 is omitted.

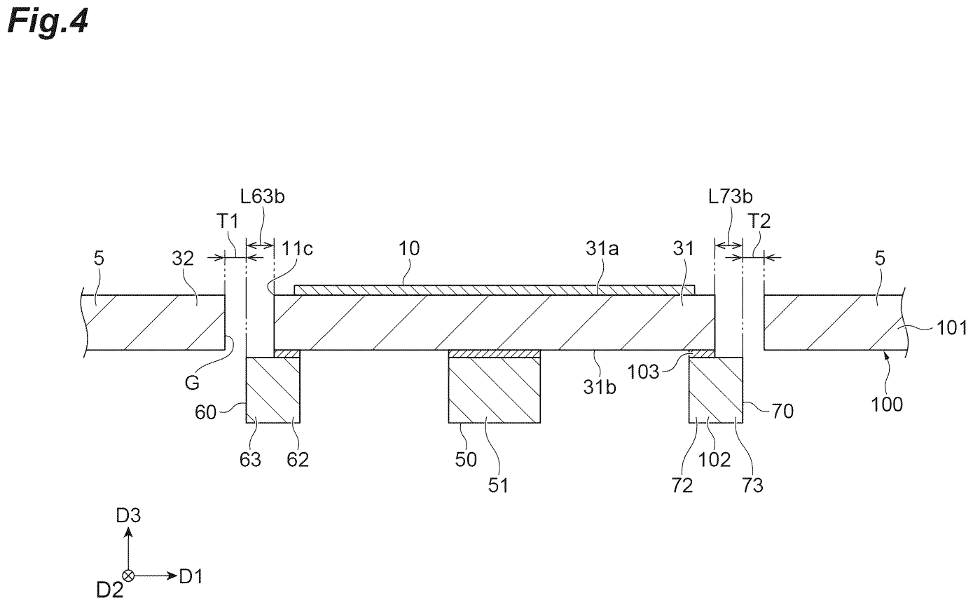

The support portion 2, the first movable portion 3, the second movable portion 4, the pair of first torsion bars 5, and the pair of second torsion bars 6 are integrally formed, for example, from a silicon on insulator (SOI) substrate 100 (refer to FIG. 4). Namely, the mirror device 1 is configured as a MEMS device manufactured by processing a semiconductor substrate using MEMS technology (patterning, etching, and the like). The SOI substrate 100 includes a first semiconductor layer 101; a second semiconductor layer 102; and an insulating layer 103 disposed between the first semiconductor layer 101 and the second semiconductor layer 102. For example, the first semiconductor layer 101 and the second semiconductor layer 102 are made of silicon, and the insulating layer 103 is made of silicon dioxide.

The magnetic field generation portion 9 is made up of, for example, a plurality of permanent magnets arranged in a Halbach array. The magnetic field generation portion 9 generates a magnetic field acting on coils 14 and 15 to be described later. The support portion 2 has, for example, a quadrangular outer shape in a plan view (when viewed in the direction D3), and is formed in a frame shape. The support portion 2 is formed from the first semiconductor layer 101, the second semiconductor layer 102, and the insulating layer 103. The support portion 2 is disposed on one side of the magnetic field generation portion 9 in the direction D3. The support portion 2 supports the first movable portion 3, the second movable portion 4, and the like. The first movable portion 3 is disposed inside the support portion 2 in a state where the first movable portion 3 is separated from the magnetic field generation portion 9. The first movable portion 3 has a shape that is symmetrical with respect to each of the X-axis and the Y-axis in a plan view. The first movable portion 3 includes a body portion 31, an ring-shaped portion 32, a first connection portion 33, and a second connection portion 34. The body portion 31, the ring-shaped portion 32, the first connection portion 33, and the second connection portion 34 are formed from the first semiconductor layer 101.

The body portion 31 is formed, for example, in a circular shape in a plan view. A center P (center of gravity) of the body portion 31 (center of the first movable portion 3) in a plan view coincides with the intersection point of the X-axis and the Y-axis. Namely, the X-axis and the Y-axis pass through the center P. The body portion 31 has a first surface 31a and a second surface 31b opposite to the first surface 31a (refer to FIG. 4). The first surface 31a is a surface on the one side in the direction D3, and is a surface opposite to the magnetic field generation portion 9. In this example, the first surface 31a and the second surface 31b are flat surfaces parallel to each other, and extend perpendicularly to the direction D3. The mirror surface 10 having a circular shape is formed on the first surface 31a. The mirror surface 10 is formed, for example, of a surface of a metal film made of aluminum. The mirror surface 10 is formed on substantially the entirety of the first surface 31a, but may be formed on a part of the first surface 31a.

The ring-shaped portion 32 is formed in a ring shape in a plan view, and surrounds the body portion 31 with a gap G interposed therebetween. The ring-shaped portion 32 has, for example, a substantially octagonal outer shape and a substantially circular inner shape in a plan view. The ring-shaped portion 32 is connected to the pair of first torsion bars 5 on the X-axis.

The first connection portion 33 is disposed on one side in the direction D2 with respect to the body portion 31 (upper side in FIG. 1), and the second connection portion 34 is disposed on the other side in the direction D2 with respect to the body portion 31 (lower side in FIG. 1). Each of the first connection portion 33 and the second connection portion 34 connects the ring-shaped portion 32 to the body portion 31. The gap G (space) is formed between the ring-shaped portion 32 and the body portion 31 except for locations where the first connection portion 33 and the second connection portion 34 are disposed. In a plan view, the gap G includes a portion at which the width (width in a direction perpendicular to an extending direction of the gap G) becomes wider as the gap G extends from an X-axis side toward a first connection portion 33 (second connection portion 34) side in the direction D2. In addition, in a plan view, the ring-shaped portion 32 includes a portion at which the width (width in a direction perpendicular to an extending direction of the ring-shaped portion 32) becomes narrower as the ring-shaped portion 32 extends from the X-axis side toward the first connection portion 33 (second connection portion 34) side in the direction D2. Since the width of the ring-shaped portion 32 is gradually narrowed as the ring-shaped portion 32 extends from the X-axis side toward the first connection portion 33 (second connection portion 34) side, dynamic distortion that occurs in the first torsion bars 5 and the second torsion bars 6 during swinging and that is transmitted to the ring-shaped portion 32, or static distortion that occurs due to the formation of a coil or the like in the second movable portion 4 and that is transmitted to the ring-shaped portion 32 via the first torsion bars 5 can be suitably relieved by the ring-shaped portion 32. Note that unlike the torsion bars (coupling portions) that couple the movable portions so as to be swingable around the axes, the first connection portion 33 and the second connection portion 34 are not intended to swingably couple the body portion 31 to the ring-shaped portion 32.

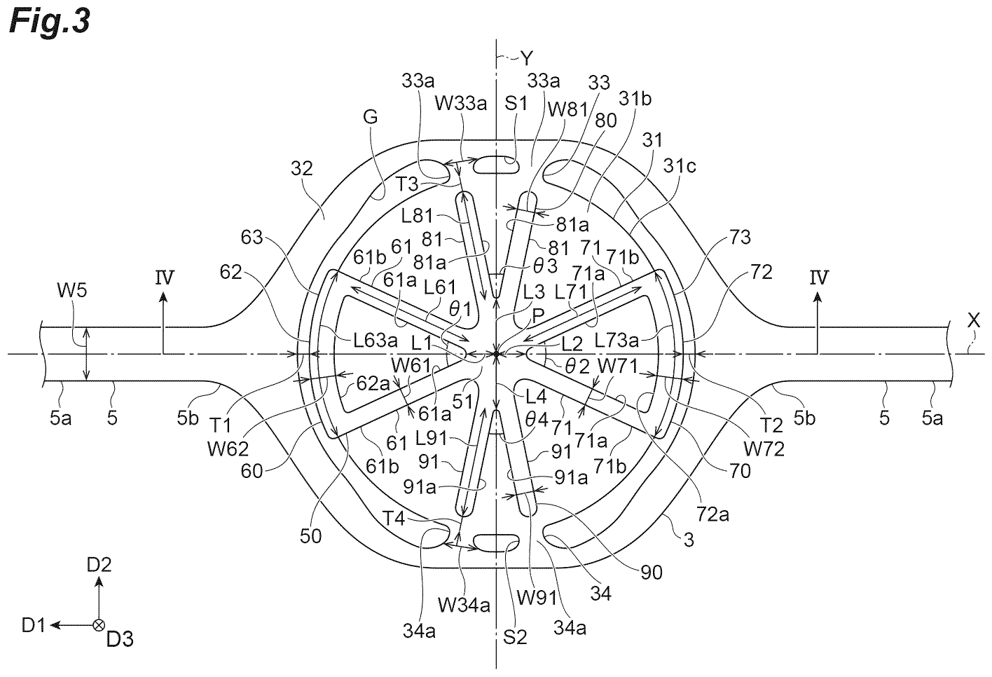

As shown in FIG. 3, the first connection portion 33 includes a pair of first connection regions 33a separated from each other by a space S1 (through-hole). In this example, the space S1 is located on the Y-axis, and the pair of first connection regions 33a face each other with the Y-axis interposed therebetween in the direction D1. Each of the first connection regions 33a is connected to the body portion 31 and the ring-shaped portion 32. The second connection portion 34 includes a pair of second connection regions 34a separated from each other by a space S2 (through-hole). In this example, the space S2 is located on the Y-axis, and the pair of second connection regions 34a face each other with the Y-axis interposed therebetween in the direction D1. Each of the second connection regions 34a is connected to the body portion 31 and the ring-shaped portion 32.

The second movable portion 4 is formed in a frame shape, and is disposed inside the support portion 2 to surround the first movable portion 3 in a state where the second movable portion 4 is separated from the magnetic field generation portion 9. The second movable portion 4 includes a pair of first connection portions 41A and 41B, a pair of second connection portions 42A and 42B, a pair of first linear portions 43A and 43B, a pair of second linear portions 44A and 44B, a pair of third linear portions 45A and 45B, and a pair of fourth linear portions 46A and 46B. Each of these portions is formed from the first semiconductor layer 101. The second movable portion 4 has a shape that is symmetrical with respect to each of the X-axis and the Y-axis in a plan view.

The first connection portions 41A and 41B are located on both sides of the first movable portion 3 in the direction D1, and extend along the direction D2. The second connection portions 42A and 42B are located on both sides of the first movable portion 3 in the direction D2, and extend along the direction D1. An inner edge of each of the second connection portions 42A and 42B in a plan view includes a concave portion 48 recessed in the direction D2, and an outer edge of each of the second connection portions 42A and 42B in a plan view includes a convex portion 49 protruding in the direction D2. The concave portion 48 and the convex portion 49 are located on the Y-axis in a plan view.

The first linear portions 43A and 43B are located on both sides of the second connection portion 42A in the direction D1, and extend along the direction D1 to be connected to the second connection portion 42A. The second linear portions 44A and 44B are located on both sides of the second connection portion 42B in the direction D1, and extend along the direction D1 to be connected to the second connection portion 42B.

The third linear portions 45A and 45B are located opposite to the second connection portion 42A with respect to the first linear portions 43A and 43B, respectively, and are connected to the first linear portions 43A and 43B and the first connection portions 41A and 41B, respectively. The fourth linear portions 46A and 46B are located opposite to the second connection portion 42B with respect to the second linear portions 44A and 44B, respectively, and are connected to the second linear portions 44A and 44B and the first connection portions 41A and 41B, respectively. The third linear portions 45A and 45B and the fourth linear portions 46A and 46B extend along a direction inclined at 45 degrees with respect to the X-axis and the Y-axis in a plan view.

A rib portion 47 is formed on surfaces on a magnetic field generation portion 9 side of the connection portions 41A to 42B and the linear portions 43A to 46B (refer to FIG. 2). The rib portion 47 is formed from the second semiconductor layer 102 and the insulating layer 103. The rib portion 47 extends in an annular shape to surround the first movable portion 3 in a plan view. A width of the rib portion 47 on the first connection portions 41A and 41B and the linear portions 45A to 46B is narrower than a width of the rib portion 47 on the second connection portions 42A and 42B and the linear portions 43A to 44B.

The first torsion bars 5 and the second torsion bars 6 are formed from the first semiconductor layer 101. The pair of first torsion bars 5 are disposed on both sides of the first movable portion 3 on the X-axis. The first torsion bars 5 couple the first movable portion 3 (ring-shaped portion 32) to the second movable portion 4 on the X-axis such that the first movable portion 3 is swingable around the X-axis (with the X-axis as a center line). In addition, the first torsion bars 5 are connected to the support portion 2 via the second movable portion 4 and the second torsion bars 6. Namely, the first torsion bars 5 can also be deemed to couple the first movable portion 3 to the support portion 2 such that the first movable portion 3 is swingable around the X-axis. The pair of first torsion bars 5 are connected to the second movable portion 4 at the first connection portions 41A and 41B, respectively. In this example, the first torsion bars 5 are formed in a plate shape extending along a plane parallel to the mirror surface 10, and are torsionally deformed when the first movable portion 3 swings around the X-axis.

Each of the first torsion bars 5 includes a linear portion 5a extending along the X-axis and having a constant width, and a pair of widened portions 5b connected to both ends of the linear portion 5a. The first torsion bars 5 is connected to the first movable portion 3 at one widened portion 5b, and is connected to the second movable portion 4 at the other widened portion 5b. In a plan view, the width of the one widened portion 5b becomes wider as the one widened portion 5b approaches the first movable portion 3, and the width of the other widened portion 5b becomes wider as the other widened portion 5b approaches the second movable portion 4. Each of the widened portions 5b is provided to relieve stress acting on a connection location between the first torsion bar 5 and the first movable portion 3 or the second movable portion 4 when the first movable portion 3 swings around the X-axis. Namely, since the widened portions 5b are provided, stress when the first movable portion 3 swings around the X-axis is relieved by the widened portions 5b, and stress acting on the first movable portion 3 (ring-shaped portion 32) is reduced, so that dynamic distortion in the body portion 31 can be suppressed. Incidentally, at least one of the pair of widened portions 5b may not be provided.

The pair of second torsion bars 6 are disposed on both sides of the second movable portion 4 on the Y-axis. The second torsion bars 6 couple the second movable portion 4 to the support portion 2 on the Y-axis such that the second movable portion 4 is swingable around the Y-axis (with the Y-axis as a center line). The pair of second torsion bars 6 are connected to the second movable portion 4 at the second connection portions 42A and 42B, respectively. The second torsion bars 6 are torsionally deformed when the second movable portion 4 swings around the Y-axis. In this example, the second torsion bars 6 extend in a meandering manner in a plan view. Each of the second torsion bars 6 includes a plurality of linear portions 11 and a plurality of folded portions 12. The plurality of linear portions 11 extend along the direction D2, and are disposed side by side in the direction D1. The plurality of folded portions 12 alternately couple both ends of the linear portions 11 adjacent to each other.

In this example, for the purpose of increasing the resonance frequency around the X-axis, a spring constant of the first torsion bars 5 is set to be larger than a spring constant of the second torsion bars 6. When the cross-sectional area (cross-sectional area in a cross-section perpendicular to an extending direction) of each torsion bar is increased, the spring constant increases. In this example, the first torsion bars 5 and the second torsion bars 6 have substantially the same thickness in the direction D3, whereas the first torsion bars 5 has a larger width (width in a direction perpendicular to the extending direction), and as a result, the cross-sectional area of the first torsion bars 5 is increased.

The mirror device 1 further includes a pair of the coils 14 and 15. Each of the coils 14 and 15 is provided in the second movable portion 4 to surround the first movable portion 3, and extends in a spiral shape in a plan view. The coils 14 and 15 are disposed along a plane including the X-axis and the Y-axis. Each of the coils 14 and 15 is wound around the first movable portion 3 a plurality of times. For example, the coils 14 and 15 are alternately arranged in a width direction of the second movable portion 4 in a plan view. The coils 14 and 15 are configured, for example, as Damascene wirings embedded in the second movable portion 4.

In FIG. 1, a disposition region R where the coils 14 and 15 are disposed is shown by hatching. The coils 14 and 15 extend in the connection portions 41A to 42B and the linear portions 43A to 46B of the second movable portion 4 along extending directions thereof. For example, each of the coils 14 and 15 is electrically connected to an electrode pad on the support portion 2 via wirings extending through the second torsion bars 6, and is electrically connected to a drive source or the like disposed outside the mirror device 1. The coils 14 and 15 can be used not only as drive coils, but also as monitor coils for checking the vibration state of the device by measuring a counter-electromotive force generated in the coils 14 and 15.

In the mirror device 1 configured as described above, when a drive signal for linear motion is input to the coil 14, a Lorentz force acts on the coil 14 due to interaction with a magnetic field generated by the magnetic field generation portion 9. By using the balance between the Lorentz force and the elastic force of the second torsion bars 6, the first movable portion 3 (mirror surface 10) can be linearly moved around the Y-axis together with the second movable portion 4.

On the other hand, when a drive signal for resonance motion is input to the coil 15, a Lorentz force acts on the coil 15 due to interaction with a magnetic field generated by the magnetic field generation portion 9. By using the resonance of the first movable portion 3 at a resonance frequency in addition to the Lorentz force, the first movable portion 3 (mirror surface 10) can be resonantly moved around the X-axis. Specifically, when a drive signal with a frequency equal to the resonance frequency of the first movable portion 3 around the X-axis is input to the coil 15, the second movable portion 4 vibrates slightly around the X-axis at the frequency. The vibration is transmitted to the first movable portion 3 via the first torsion bars 5, so that the first movable portion 3 can swing around the X-axis at the frequency.

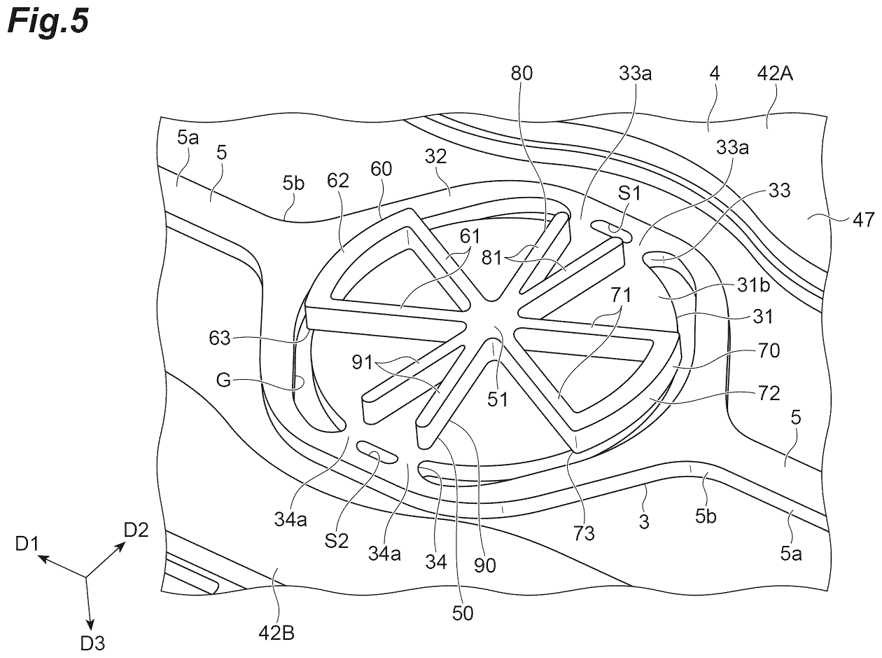

As shown in FIGS. 2 to 6, a rib portion 50 (rib) is formed on the second surface 31b of the body portion 31 of the first movable portion 3. The rib portion 50 is a reinforcing rib for reinforcing the first movable portion 3, and is configured as a reinforcing structure extending along a predetermined direction. The rib portion 50 is formed from the second semiconductor layer 102 and the insulating layer 103. In this example, the rib portion 50 has a shape that is symmetrical with respect to each of the X-axis and the Y-axis in a plan view. The rib portion 50 includes a central portion 51, a first rib portion 60, a second rib portion 70, a third rib portion 80, and a fourth rib portion 90.

The central portion 51 is a reference portion disposed at a reference position in a plan view. In this example, the reference position coincides with the center P of the body portion in a plan view, and the central portion 51 is disposed on the center P. In the present embodiment, the central portion 51 has an elongated shape in the direction D2 in a plan view. The central portion 51 may be formed such that a width in the direction D1 and a width in the direction D2 are substantially the same. A distance L1 from the center P of the central portion 51 to a location where inner edges 61a of a pair of first portions 61 of the first rib portion 60 to be described later are connected is larger than a width W61 of the first portions 61. Accordingly, sufficient rigidity can be ensured at the central portion 51, and damage to the rib portion 50 or the peeling of the rib portion 50 from the body portion 31 can be prevented. The same applies to a second rib portion 70 side. Namely, a distance L2 from the center P of the central portion 51 to a location where inner edges 71a of a pair of second portions 71 of the second rib portion 70 to be described later are connected is larger than a width W71 of the second portions 71. In addition, a distance L3 from the center P of the central portion 51 to a location where inner edges 81a of a pair of third portions 81 of the third rib portion 80 to be described later are connected is larger than a width W81 of the third portions 81. Even with this configuration, sufficient rigidity can be ensured at the central portion 51, and damage to the rib portion 50 or the peeling of the rib portion 50 from the body portion 31 can be prevented. The same applies to a fourth rib portion 90 side. Namely, a distance L4 from the center P of the central portion 51 to a location where inner edges 91a of a pair of fourth portions 91 of the fourth rib portion 90 to be described later are connected is larger than a width W91 of the fourth portions 91.

The first rib portion 60 includes the pair of first portions 61 and a first extending portion 62 (first connecting portion). The pair of first portions 61 extend from the central portion 51 (from the side of the center P that is a reference position) toward one side (left side in FIG. 3) in the direction D1, and face each other with the X-axis interposed therebetween in the direction D2. The pair of first portions 61 extend straight along directions inclined with respect to the direction D1 and the direction D2 in a plan view. In this example, the pair of first portions 61 extend along a radial direction of a circle centered on the center P.

The pair of first portions 61 are connected to each other at the central portion 51 (at the side of the center P that is a reference position). In this example, the pair of first portions 61 are connected to each other via the central portion 51 (integrated). In a plan view, the inner edges 61a of the pair of first portions 61 are smoothly connected to each other. The fact that “edges A and B are smoothly connected” means that there is no sharp location (for example, the vertex of a corner (including all cases of an acute angle, a right angle, and an obtuse angle)) between the edges A and B and the edges A and B are connected such that the curvature is continuous between the edges A and B. In this example, the inner edges 61a are smoothly connected by an outer edge of the central portion 51 formed in an arc shape.

The first extending portion 62 extends between the pair of first portions 61 in a plan view. In this example, the first extending portion 62 extends to intersect the X-axis in a plan view, and is connected to the pair of first portions 61. In more detail, the first extending portion 62 is connected to end portions 61b on an opposite side of the pair of first portions 61 from the central portion 51. In a plan view, an inner edge 62a of the first extending portion 62 is smoothly connected to the inner edges 61a of the pair of first portions 61. In this example, an R portion that is curved in an arc shape is formed between the inner edges 61a and 62a, and accordingly, the inner edges 61a and 62a are smoothly connected. The first extending portion 62 extends along an outer edge 31c of the body portion 31 of the first movable portion 3 in a plan view. In addition, the first extending portion 62 is curved to be convex toward the one side (side opposite to the central portion 51) in the direction D1 in a plan view. In this example, the outer edge 31c has an arc shape, and the first extending portion 62 is formed in an arc shape that is convex toward the one side in the direction D1.

A width W62 of the first extending portion 62 is wider than the width W61 of each of the first portions 61. The width W61 of the first portion 61 is a width of the first portion 61 along a direction perpendicular to an extending direction (direction from the center P toward the end portion 61b) of the first portion 61 in a plan view. The width W62 of the first extending portion 62 is a width of the first extending portion 62 along a direction perpendicular to an extending direction (direction along the outer edge 31c) of the first extending portion 62 in a plan view. These points also apply to the width W71 of the second portions 71 and a width W72 of a second extending portion 72 to be described later, as well as the width W81 of the third portions 81 and the width W91 of the fourth portions 91 described above.

Each of the width W61 of the first portions 61 and the width W71 of the second portions 71 is more than or equal to each of the width W81 of the third portions 81 and the width W91 of the fourth portions 91. Accordingly, the strength of the first rib portion 60 and the second rib portion 70 can be sufficiently ensured while suppressing an increase in the moment of inertia around the X-axis. It is more preferable that each of the width W61 and the width W71 is larger than each of the width W81 and the width W91. In addition, each of the width W62 of the first extending portion 62 and the width W72 of the second extending portion 72 is more than or equal to each of the width W81 of the third portions 81 and the width W91 of the fourth portions 91. Accordingly, the strength of the first rib portion 60 and the second rib portion 70 can be sufficiently ensured while suppressing an increase in the moment of inertia around the X-axis. It is more preferable that each of the width W62 and the width W72 is larger than each of the width W81 and the width W91.

The first extending portion 62 includes a protrusion portion 63 protruding outward (side opposite to the center P) from the outer edge 31c (boundary between the body portion 31 and the gap G) of the body portion 31 in a plan view. Namely, the protrusion portion 63 is located outside the outer edge 31c in a plan view. An inner portion (portion other than the protrusion portion 63) of the first extending portion 62 does not protrude outward from the outer edge 31c. In a plan view, the entirety of a region surrounded by the first extending portion 62, the pair of first portions 61, and the central portion 51 overlaps the body portion 31. The region is a region where the rib portion 50 is not formed (region with no rib). Since the region where the rib portion 50 is not formed is provided on the body portion 31 in such a manner, the strength of the rib portion 50 can be improved while suppressing an increase in the moment of inertia in the first movable portion 3.

The protrusion portion 63 extends along the outer edge 31c of the body portion 31. In this example, the protrusion portion 63 is provided over the entirety of the first extending portion 62 in the extending direction (direction along the outer edge 31c) of the first extending portion 62, and is formed in an arc shape that is convex toward the one side (side opposite to the central portion 51) in the direction D1. Namely, the protrusion portion 63 is provided to extend between the pair of first portions 61 in the direction along the outer edge 31c, and protrudes outward from the outer edge 31c on the X-axis (intersects the X-axis in a plan view). The protrusion portion 63 can also be deemed to extend along the outer edge 31c from the X-axis toward the one side and the other side in the direction D2. The protrusion portion 63 overlaps the gap G formed between the body portion 31 and the ring-shaped portion 32 of the first movable portion 3 in a plan view. The protrusion portion 63 is not in contact with portions other than the body portion 31 (for example, the ring-shaped portion 32, the first torsion bars 5, the first connection portion 33, the second connection portion 34, and the like). Namely, in this example, the protrusion portion 63 is a portion floating in space without being supported by the portions other than the body portion 31. The protrusion portion 63 does not overlap the ring-shaped portion 32 in a plan view (does not reach the ring-shaped portion 32), and there is a gap between the protrusion portion 63 and the ring-shaped portion 32 in a plan view.

A distance T1 between the protrusion portion 63 and the ring-shaped portion 32 on the X-axis is smaller than a minimum width W5 of the first torsion bars 5 in the direction D2. A length L63a of the protrusion portion 63 along the outer edge 31c of the body portion 31 is larger than the minimum width W5 of the first torsion bars 5 in the direction D2. The length L63a is larger than the width W62 of the first extending portion 62. The length L63a is larger than the distance T1. The length L63a is larger than a maximum width W33a of the first connection regions 33a that connect the ring-shaped portion 32 and the body portion 31. The length L63a is larger than a maximum width of the entirety of the first connection portion 33 (region formed by the pair of first connection regions 33a and the space S1). A protrusion length L63b of the protrusion portion 63 from the outer edge 31c of the body portion 31 (refer to FIG. 4) is smaller than the minimum width W5 of the first torsion bars 5 in the direction D2. The width of the first torsion bars 5 is a width of the first torsion bars 5 along the direction (in this example, the direction D2) perpendicular to the extending direction (in this example, the direction D1) of the first torsion bars 5 in a plan view. The protrusion length L63b is a maximum protrusion length (maximum width) of the protrusion portion 63 in a direction (in this example, a radial direction of a circle centered on the center P) perpendicular to an extending direction (in this example, a circumferential direction of the circle centered on the center P) of the outer edge 31c in a plan view. Namely, when the outer edge 31c has a curvature, the extending direction of the outer edge 31c is a tangential direction. This point also applies to a protrusion length L73b of a protrusion portion 73 to be described later.

The second rib portion 70 has a shape that is symmetrical to the first rib portion 60 with respect to the Y-axis. The second rib portion 70 includes the pair of second portions 71 and the second extending portion 72 (second connecting portion). The pair of second portions 71 extend from the central portion 51 (from the side of the center P that is a reference position) toward the other side (right side in FIG. 3) in the direction D1, and face each other with the X-axis interposed therebetween in the direction D2. The second portions 71 extend straight along directions inclined with respect to the direction D1 and the direction D2 in a plan view. In this example, the pair of second portions 71 extend along a radial direction of a circle centered on the center P. In a plan view, one second portion 71 (the second portion 71 on the upper side in FIG. 3) is located on the same straight line as one first portion 61 (the first portion 61 on the lower side in FIG. 3) of the first rib portion 60, and the other second portion 71 (the second portion 71 on the lower side in FIG. 3) is located on the same straight line as the other first portion 61 (the first portion 61 on the upper side in FIG. 3) of the first rib portion 60. The first rib portion 60 and the second rib portion 70 as a whole have a ribbon shape in a plan view.

The pair of second portions 71 are connected to each other at the central portion 51 (at the side of the center P that is a reference position). In this example, the pair of second portions 71 are connected to each other via the central portion 51 (integrated). In a plan view, the inner edges 71a of the pair of second portions 71 are smoothly connected to each other. In this example, the inner edges 71a are smoothly connected by the outer edge of the central portion 51 formed in an arc shape.

The second extending portion 72 extends between the pair of second portions 71 in a plan view. In this example, the second extending portion 72 extends to intersect the X-axis in a plan view, and is connected to the pair of second portions 71. In more detail, the second extending portion 72 is connected to end portions 71b on an opposite side of the pair of second portions 71 from the central portion 51. In a plan view, an inner edge 72a of the second extending portion 72 is smoothly connected to the inner edges 71a of the pair of second portions 71. In this example, an R portion that is curved in an arc shape is formed between the inner edges 71a and 72a, and accordingly, the inner edges 71a and 72a are smoothly connected. The second extending portion 72 extends along the outer edge 31c of the body portion 31 of the first movable portion 3 in a plan view. In addition, the second extending portion 72 is curved to be convex toward the other side (side opposite to the central portion 51) in the direction D1 in a plan view. In this example, the outer edge 31c has an arc shape, and the second extending portion 72 is formed in an arc shape that is convex toward the other side in the direction D1.

The width W72 of the second extending portion 72 is wider than the width W71 of each of the second portions 71. The second extending portion 72 includes the protrusion portion 73 protruding outward (side opposite to the center P) from the outer edge 31c of the body portion 31 in a plan view. Namely, the protrusion portion 73 is located outside the outer edge 31c in a plan view. An inner portion (portion other than the protrusion portion 73) of the second extending portion 72 does not protrude outward from the outer edge 31c. In a plan view, the entirety of a region surrounded by the second extending portion 72, the pair of second portions 71, and the central portion 51 overlaps the body portion 31.

The protrusion portion 73 extends along the outer edge 31c of the body portion 31. In this example, the protrusion portion 73 is provided over the entirety of the second extending portion 72 in an extending direction (direction along the outer edge 31c) of the second extending portion 72, and is formed in an arc shape that is convex toward one side (side opposite to the central portion 51) in the direction D1. Namely, the protrusion portion 73 is provided to extend between the pair of second portions 71 in the direction along the outer edge 31c, and protrudes outward from the outer edge 31c on the X-axis (intersects the X-axis in a plan view). The protrusion portion 73 can also be deemed to extend along the outer edge 31c from the X-axis toward the one side and the other side in the direction D2. The protrusion portion 73 overlaps the gap G formed between the body portion 31 and the ring-shaped portion 32 of the first movable portion 3 in a plan view. The protrusion portion 73 is not in contact with portions other than the body portion 31 (for example, the ring-shaped portion 32, the pair of first torsion bars 5, the first connection portion 33, the second connection portion 34, and the like). Namely, in this example, the protrusion portion 73 is a portion floating in space without being supported by the portions other than the body portion 31.

A distance T2 between the protrusion portion 73 and the ring-shaped portion 32 on the X-axis is smaller than the minimum width W5 of the first torsion bars 5 in the direction D2. A length L73a of the protrusion portion 73 along the outer edge 31c of the body portion 31 is larger than the minimum width W5 of the first torsion bars 5 in the direction D2. The length L73a is larger than the width W72 of the second extending portion 72. The length L73a is larger than the distance T2. A protrusion length L73b of the protrusion portion 73 from the outer edge 31c of the body portion 31 (refer to FIG. 4) is smaller than the minimum width W5 of the first torsion bars 5 in the direction D2.

The third rib portion 80 includes the pair of third portions 81. The pair of third portions 81 extend from the central portion 51 (from the side of the center P that is a reference position) toward the one side (upper side in FIGS. 2 and 3) in the direction D2, and face each other with the Y-axis interposed therebetween in the direction D1. The third portions 81 extend straight along directions inclined with respect to the direction D1 and the direction D2 in a plan view. In this example, the pair of third portions 81 extend along a radial direction of a circle centered on the center P.

The pair of third portions 81 are connected to each other at the central portion 51 (at the side of the center P that is a reference position). In this example, the pair of third portions 81 are connected to each other via the central portion 51 (integrated). In a plan view, the inner edges 81a of the pair of third portions 81 are smoothly connected to each other. In this example, an R portion that is curved in an arc shape is formed between the inner edges 81a, and accordingly, the inner edges 81a are smoothly connected.

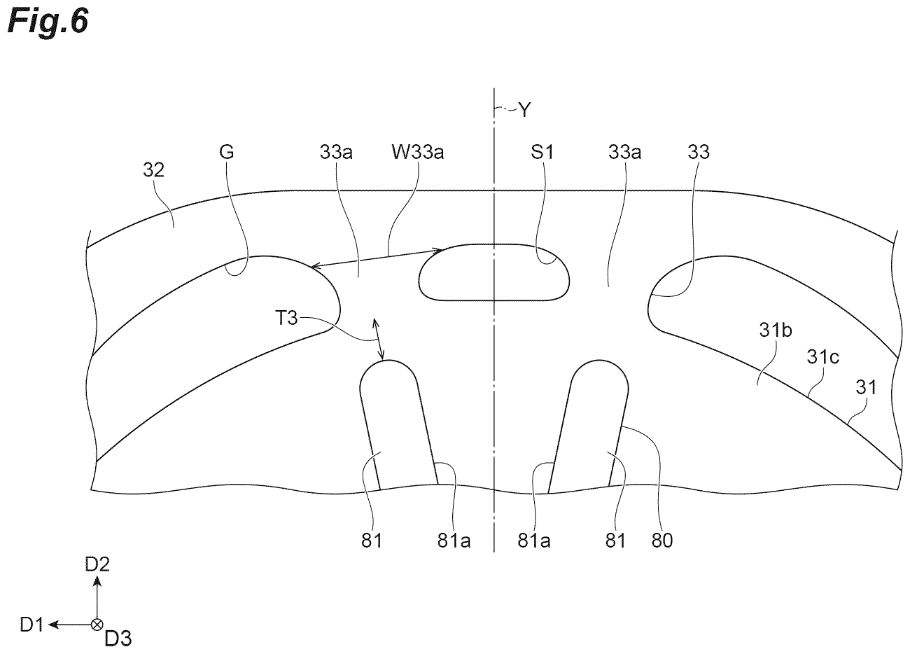

The pair of third portions 81 extend toward the pair of respective first connection regions 33a of the first connection portion 33 of the first movable portion 3. In a plan view, the third portions 81 do not reach the first connection regions 33a, and are separated from the first connection regions 33a. A distance T3 (shortest distance) between the third portions 81 and the first connection regions 33a is smaller than the maximum width W33a of the first connection regions 33a (refer to FIGS. 3 and 6). The maximum width W33a of the first connection regions 33a is a maximum width of the first connection regions 33a in directions perpendicular to directions in which the body portion 31 and the ring-shaped portion 32 are connected by the first connection regions 33a (extending directions of the first connection regions 33a). This point also applies to a maximum width W34a of the second connection regions 34a to be described later.

The rib portion 50 is not formed between the pair of third portions 81. Namely, the rib portion 50 does not include a portion formed between the pair of third portions 81. The fact that “the rib portion 50 does not include a portion formed between the pair of third portions 81” means, for example, that the rib portion 50 is not formed in a region between the pair of third portions 81 in a plan view. The central portion 51 does not correspond to “a portion formed between the pair of third portions 81”. These points also apply to the fourth portions 91 to be described later.

The fourth rib portion 90 includes the pair of fourth portions 91. The pair of fourth portions 91 extend from the central portion 51 (from the side of the center P that is a reference position) toward the other side (lower side in FIG. 3) in the direction D2, and face each other with the Y-axis interposed therebetween in the direction D1. The fourth portions 91 extend straight along directions inclined with respect to the direction D1 and the direction D2 in a plan view. In this example, the pair of fourth portions 91 extend along a radial direction of a circle centered on the center P. In a plan view, one fourth portion 91 (the fourth portion 91 on the left side in FIG. 3) is located on the same straight line as one third portion 81 (the third portion 81 on the right side in FIG. 3) of the third rib portion 80, and the other fourth portion 91 (the fourth portion 91 on the right side in FIG. 3) is located on the same straight line as the other third portion 81 (the third portion 81 on the left side in FIG. 3) of the third rib portion 80. The third rib portion 80 and the fourth rib portion 90 as a whole have an X shape in a plan view.

The pair of fourth portions 91 are connected to each other at the central portion 51 (at the side of the center P that is a reference position). In this example, the pair of fourth portions 91 are connected to each other via the central portion 51 (integrated). In a plan view, the inner edges 91a of the pair of fourth portions 91 are smoothly connected to each other. In this example, an R portion that is curved in an arc shape is formed between the inner edges 91a, and accordingly, the inner edges 91a are smoothly connected.

The pair of fourth portions 91 extend toward the pair of respective second connection regions 34a of the second connection portion 34 of the first movable portion 3. In a plan view, the fourth portions 91 do not reach the second connection regions 34a, and are separated from the second connection regions 34a. A distance T4 (shortest distance) between the fourth portions 91 and the second connection regions 34a is smaller than the maximum width W34a of the second connection regions 34a (refer to FIG. 3). The rib portion 50 is not formed between the pair of fourth portions 91. Namely, the rib portion 50 does not include a portion formed between the pair of fourth portions 91.

In the rib portion 50, the first portions 61, the second portions 71, the third portions 81, and the fourth portions 91 extend radially around the center P. The first portions 61, the second portions 71, the third portions 81, and the fourth portions 91 are different portions from one another (not shared with one another). Each of a length L61 of the first portions 61 and a length L71 of the second portions 71 is longer than each of a length L81 of the third portions 81 and a length L91 of the fourth portions 91. In this example, the lengths L61 and L71 are equal to each other, and the lengths L81 and L91 are equal to each other.

In a plan view, an angle between the pair of first portions 61 is 01, an angle between the pair of second portions 71 is θ2, an angle between the pair of third portions 81 is θ3, and an angle between the pair of fourth portions 91 is θ4, the following relationships are satisfied.

$$θ 3 < θ 1 < 3 \times θ 3 \\ θ 4 < θ 1 < 3 \times θ 4 \\ θ 3 < θ 2 < 3 \times θ 3 \\ θ 4 < θ 2 < 3 \times θ 4$$

Namely, each of θ1 and θ2 is larger than each of θ3 and θ4, and is smaller than three times each of θ3 and θ4. In this example, θ1 and θ2 are equal to each other, and θ3 and θ4 are equal to each other. Preferably, θ1 and θ2 are larger than 30 degrees, and are smaller than 90 degrees. Preferably, θ3 and θ4 are larger than 10 degrees, and are smaller than 30 degrees.

One example of the dimensions of each portion is as follows. The distance T1 between the protrusion portion 63 and the ring-shaped portion 32 on the X-axis is equal to the distance T2 between the protrusion portion 73 and the ring-shaped portion 32 on the X-axis, and is approximately 10 μm to 100 μm. The width W61 of the first portions 61 is equal to the width W71 of the second portions 71, the width W81 of the third portions 81, and the width W91 of the fourth portions 91, and is approximately 10 μm to 100 μm. The width W62 of the first extending portion 62 is equal to the width W72 of the second extending portion 72, and is approximately 20 μm to 200 μm. The length L61 of the first portions 61 is equal to the length L71 of the second portions 71, and is approximately 100 μm to 1000 μm. The distance L1 from the center P of the central portion 51 to the location where the inner edges 61a of the pair of first portions 61 are connected is equal to the distance L2 from the center P to the location where the inner edges 71a of the pair of second portions 71 are connected, and is approximately 20 μm to 200 μm. The distance L3 from the center P to the location where the inner edges 81a of the pair of third portions 81 described later are connected is equal to the distance L4 from the center P to the location where the inner edges 91a of the pair of fourth portions 91 are connected, and is approximately 30 μm to 300 μm.

The length L63a of the protrusion portion 63 along the outer edge 31c of the body portion 31 is equal to the length L73a of the protrusion portion 73 along the outer edge 31c of the body portion 31, and is approximately 100 μm to 1000 μm. The maximum width W33a of the first connection regions 33a is equal to the maximum width W34a of the second connection regions 34a, and is approximately 20 μm to 200 μm. The distance T3 between the third portions 81 and the first connection regions 33a is equal to the distance T4 between the fourth portions 91 and the second connection regions 34a, and is approximately 10 μm to 100 μm. The protrusion length L63b of the protrusion portion 63 from the outer edge 31c of the body portion 31 is equal to the protrusion length L73b of the protrusion portion 73 from the outer edge 31c of the body portion 31, and is approximately 5 μm to 60 μm. A thickness of the first semiconductor layer 101 is approximately 20 μm to 200 μm. A thickness of the rib portion 50 is approximately 20 μm to 200 μm.

### Functions and Effects

In the mirror device 1, the rib portion 50 includes the first extending portion 62 (first connecting portion) and the second extending portion 72 (second connecting portion) extending along the outer edge 31c of the body portion 31 in a plan view (when viewed in the direction D3 perpendicular to the second surface 31b). Accordingly, the rigidity of the body portion 31 at the outer edge portion at which distortion is likely to occur can be increased, and distortion of the body portion 31 (in other words, distortion of the mirror surface 10) can be effectively suppressed. On the other hand, from the viewpoint of effectively suppressing distortion of the body portion 31, it is preferable that the rib portion is formed close to the outer edge 31c of the body portion 31; however, for example, when the extending portions 62 and 72 are formed such that the side surfaces of the extending portions 62 and 72 are flush with the side surface of the body portion 31 (such that the side surfaces of the extending portions 62 and 72 coincide with the side surface of the body portion 31 when viewed in the direction D3), it is concerned that the devices in which the extending portions 62 and 72 protrude from the outer edge 31c of the body portion 31 and the devices in which the extending portions 62 and 72 do not protrude from the outer edge 31c of the body portion 31 coexist due to manufacturing errors (for example, etching errors). In this case, for example, it may be difficult to set manufacturing conditions in a post-process. For example, in the manufacturing process of the mirror device 1, a protection film is formed on a front side of the body portion 31 (first surface 31a side on which the mirror surface 10 is formed), and then a back surface side (second surface 31b side) of the body portion 31 including the rib portion 50 is etched. In addition, after the back surface etching, etching is performed to remove the protection film. For example, when the devices in which the extending portions 62 and 72 protrude from the outer edge 31c of the body portion 31 and the devices in which the extending portions 62 and 72 do not protrude from the outer edge 31c of the body portion 31 coexist due to manufacturing errors, etching conditions (etching time and the like) required to remove the protection film are changed, so that it may be difficult to set manufacturing conditions. For example, in a case where optimal etching conditions for removal of the protection film in the device in which the rib portion 50 protrudes from the outer edge 31c of the body portion 31 are set, when the device in which the rib portion 50 does not protrude from the outer edge 31c of the body portion 31 is subjected to etching under the same conditions, a situation where not only the protection film but also portions such as the body portion 31 where etching is not originally desired is etched can occur. In this regard, in the mirror device 1, in a plan view, the extending portions 62 and 72 include the protrusion portions 63 and 73 protruding outward (side opposite to the body portion 31) from the outer edge 31c of the body portion 31 and extending along the outer edge 31c of the body portion 31. Accordingly, the occurrence of such a situation can be avoided, and manufacturing can be facilitated. Therefore, according to the mirror device 1, distortion of the mirror surface 10 can be effectively suppressed, and manufacturing can be facilitated.

Distortion that occurs in the body portion 31 includes dynamic distortion and static distortion. The dynamic distortion is distortion that occurs when the first torsion bars 5 are torsionally deformed to cause the first movable portion 3 to swing. The dynamic distortion also occurs because stress generated in the first torsion bars 5 when the first torsion bars 5 are torsionally deformed is transmitted to the body portion 31 via the ring-shaped portion 32. The static distortion is distortion that occurs due to the formation of the mirror surface 10 and the protection film. The static distortion also occurs due to a difference in thermal expansion coefficient between different materials (for example, silicon that is the material of the SOI substrate 100, SiN that is the material of the insulating layer, a metal material constituting the coils 14 and 15, and the like). Both the dynamic distortion and the static distortion are particularly likely to occur at the outer edge portion of the body portion 31. Specifically, the dynamic distortion is likely to occur in the vicinities of the connection locations between the first movable portion 3 and the first torsion bars 5 where stress occurs during swinging of the first movable portion 3, or at a position away from the X-axis (swing axis) which is strongly affected by the moment of inertia. The static distortion is likely to occur at the outer edge portion of the body portion 31 due to the influence of a metal film or an inorganic material film laminated on the body portion 31. In addition, the static distortion is also likely to occur in the vicinities of the connection locations between the first movable portion 3 and the first torsion bars 5. The reason is that distortion occurring in the second movable portion 4 due to the formation of the coils 14 and 15 (or a piezoelectric element in the case of piezoelectric drive) can be transmitted to the first movable portion 3 via the first torsion bars 5. When distortion occurs in the body portion 31 (mirror surface 10), an adverse influence such as the distortion of a laser rib with which the mirror surface 10 is irradiated can occur. For that reason, as described above, in the mirror device 1, the extending portions 62 and 72 extending along the outer edge 31c of the body portion 31 are provided, so that rigidity at the outer edge portion of the body portion 31 is increased, and distortion of the body portion 31 is suppressed.

The lengths L63a and L73a of the protrusion portions 63 and 73 along the outer edge 31c of the body portion 31 are larger than the minimum width W5 of the first torsion bars 5 in the direction D2 (direction perpendicular to both the directions D1 and D3). Accordingly, distortion of the body portion 31 can be more effectively suppressed.

The protrusion lengths L63b and L73b of the protrusion portions 63 and 73 from the outer edge 31c of the body portion 31 are smaller than the minimum width W5 of the first torsion bars 5 in the direction D2. Accordingly, the downsizing of the mirror device 1 can be achieved while suppressing distortion of the body portion 31. The protrusion lengths L63b and L73b are set to a minimum protrusion amount, for example, in consideration of processing tolerances.

In a plan view, the rib portion 50 includes the pair of first portions 61 extending from the central portion 51 (from the side of the reference position) toward the one side in the direction D1 (predetermined direction) (direction parallel to the X-axis) and facing each other in the direction D2; the first extending portion 62 (first connecting portion) connected to the pair of first portions 61; the pair of second portions 71 extending from the central portion 51 toward the other side in the direction D1 and facing each other in the direction D2; and the second extending portion 72 (second connecting portion) connected to the pair of second portions 71. The first extending portion 62 and the second extending portion 72 extend along the outer edge 31c of the body portion 31. Accordingly, while distortion of the entirety of the body portion 31 can be suppressed by the first portions 61 and the second portions 71, distortion of the outer edge portion of the body portion 31 can be suppressed by the first extending portion 62 and the second extending portion 72.

The width W62 of the first extending portion 62 is wider than the width W61 of each of the first portions 61, and the width W72 of the second extending portion 72 is wider than the width W71 of each of the second portions 71. Accordingly, the rigidity of the body portion 31 at the outer edge portion at which distortion is likely to occur can be increased, and distortion of the body portion 31 can be more effectively suppressed.

The pair of first portions 61 are connected to each other at the central portion 51 (at the reference position), and the pair of second portions 71 are connected to each other at the central portion 51. Accordingly, the rigidity of the rib portion 50 can be increased, and damage to the rib portion 50 or the peeling of the rib portion 50 can be suppressed.

In a plan view, the inner edges 61a of the pair of first portions 61 are smoothly connected to each other, and the inner edges 71a of the pair of second portions 71 are smoothly connected to each other. Accordingly, damage to the rib portion 50 or the peeling of the rib portion 50 can be further suppressed.

The reference position coincides with the center P of the body portion 31 in a plan view. Accordingly, the rib portion 50 can be disposed on the body portion 31 in a well-balanced manner, and distortion of the body portion 31 can be more effectively suppressed.

In a plan view, the rib portion 50 includes the pair of third portions 81 extending from the central portion 51 toward the one side in the direction D2 and facing each other in the direction D1, and the pair of fourth portions 91 extending from the central portion 51 toward the other side in the direction D2 and facing each other in the direction D1. Accordingly, distortion of the body portion 31 can be more effectively suppressed.

In a plan view, the angle θ1 between the pair of first portions 61 is larger than the angle θ3 between the pair of third portions 81. Accordingly, the length (length along the outer edge 31c of the body portion 31) of the first extending portion 62 connected to the pair of first portions 61 can be lengthened, and distortion of the body portion 31 can be more effectively suppressed.

The first movable portion 3 includes the ring-shaped portion 32 surrounding the body portion 31 with the gap G interposed therebetween in a plan view and connected to the first torsion bars 5 (coupling portions), and the first connection portion 33 and the second connection portion 34 that connect the ring-shaped portion 32 to the body portion 31, and parts of the protrusion portions 63 and 73 overlap the gap G in a plan view. Accordingly, the body portion 31 is connected to the first torsion bars 5 via the ring-shaped portion 32, so that the occurrence that stress generated in the first torsion bars 5 during swinging of the first movable portion 3 is directly transmitted to the body portion 31 can be suppressed, and dynamic distortion of the body portion 31 can be suppressed.

The protrusion portion 63 does not overlap the ring-shaped portion 32 in a plan view. Accordingly, the occurrence that stress generated in the first torsion bars 5 during swinging of the first movable portion 3 is transmitted to the body portion 31 can be suppressed, and dynamic distortion of the body portion 31 can be suppressed. In addition, the occurrence that stress generated in the ring-shaped portion 32 is transmitted to the body portion 31 via the rib portion 50 can be suppressed, and distortion (static distortion) of the body portion 31 can be suppressed.

The first connection portion 33 and the second connection portion 34 are disposed on the one side and the other side in the direction D2 with respect to the body portion 31, respectively, and the rib portion 50 includes the pair of first portions 61, the first extending portion 62, the pair of second portions 71, and the second extending portion 72. The first extending portion 62 and the second extending portion 72 extend along the outer edge 31c of the body portion 31. Accordingly, the first connection portion 33 and the second connection portion 34 are disposed on the one side and the other side in the direction D2 with respect to the body portion 31, respectively, so that the first connection portion 33 and the second connection portion 34 can be disposed at positions away from the first torsion bars 5, and the occurrence that stress generated in the first torsion bars 5 during swinging of the first movable portion 3 is transmitted to the body portion 31 can be further suppressed. In addition, by forming the rib portion 50 so as to include the first portions 61, the first extending portion 62, the second portions 71, and the second extending portion 72, distortion of the body portion 31 can be suppressed while suppressing an increase in the moment of inertia of the first movable portion 3 around the X-axis.

The protrusion portions 63 and 73 protrude outward from the outer edge 31c of the body portion 31 on the X-axis, and the distances T1 and T2 between the protrusion portions 63 and 73 and the ring-shaped portion 32 on the X-axis are smaller than the minimum width W5 of the first torsion bars 5 in the direction D2. Accordingly, the downsizing of the mirror device 1 can be achieved.

The first extending portion 62 and the second extending portion 72 extend to intersect the X-axis in a plan view. Static distortion is likely to occur at a position far from the first connection portion 33 and the second connection portion 34 (for example, a position on the X-axis); however, according to the mirror device 1, distortion of the body portion 31 at this position can be effectively suppressed. In addition, the moment of inertia of the first movable portion 3 can be reduced compared to a case where the first extending portion 62 and the second extending portion 72 are disposed at positions away from the X-axis.

The rib portion 50 includes the pair of third portions 81 and the pair of fourth portions 91. Stress generated in the first torsion bars 5 during swinging of the first movable portion 3 is likely to be transmitted to positions close to the first connection portion 33 and the second connection portion 34, and dynamic distortion is likely to occur at these positions; however, according to the mirror device 1, distortion of the body portion 31 at these position can be effectively suppressed.

The protrusion portions 63 and 73 are not in contact with portions other than the body portion 31. Accordingly, the transmission of stress from the portions other than the body portion 31 to the body portion 31 via the rib portion 50 can be suppressed. In addition, the size of the rib portion 50 can be reduced, and an increase in the moment of inertia of the first movable portion 3 can be suppressed.

The body portion 31 is formed from the first semiconductor layer 101, and the rib portion 50 is formed from the second semiconductor layer 102 and the insulating layer 103. In the mirror device 1 as well, the above-described actions and effects such as being able to effectively suppress distortion of the mirror surface 10 and being able to facilitate manufacturing can be achieved.

The present disclosure is not limited to the above-described embodiment and modification examples. For example, the material and shape of each configuration are not limited to the material and shape described above, and various materials and shapes can be adopted. For example, the body portion 31, the ring-shaped portion 32, and the mirror surface 10 may be formed in any shape such as a circular shape, an elliptical shape, a quadrangular shape, or a rhombus shape. The shape of the second movable portion 4 is not limited to the above-described shape.

In the above-described embodiment, the first movable portion 3 may include only the body portion 31 without including the ring-shaped portion 32, the first connection portion 33, and the second connection portion 34. In this case, the first torsion bars 5 are directly connected to the body portion 31. In such a configuration, the protrusion portions 63 and 73 may protrude outward from the outer edge 31c (boundary between the body portion 31 and the space outside the body portion 31) of the body portion 31 in a plan view. Parts of the protrusion portions 63 and 73 may be provided to overlap the first movable portion 3 (for example, the first connection portion 33 and the second connection portion 34) in a plan view, but are provided such that at least parts thereof do not overlap the first movable portion 3 in a plan view.

The rib portion 50 may include at least the protrusion portions 63 and 73, the first rib portion 60 may not include the pair of first portions 61, and the second rib portion 70 may not include the pair of second portions 71. The rib portion 50 may not include the third rib portion 80 and the fourth rib portion 90. In the above-described embodiment, the pair of first portions 61 are connected to each other at the central portion 51; however, the pair of first portions 61 may not be connected to each other on a central portion 51 side (the side of the reference position) (may be separated from each other). For example, in the above-described embodiment, the central portion 51 may be omitted. Namely, the pair of first portions 61 may extend from the side of the reference position toward the one side in the direction D1. This point also applies to the pair of second portions 71, the pair of third portions 81, and the pair of fourth portions 91. The rib portion 50 may include only one of the protrusion portions 63 and 73 (the first rib portion 60 and the second rib portion 70).

In the above-described embodiment, the protrusion portions 63 and 73 are provided to protrude from the outer edge 31c of the body portion 31 on the X-axis; however, the protrusion portions 63 and 73 may be provided to protrude from the outer edge 31c on the Y-axis. For example, the pair of first portions 61 may be provided to extend from the central portion 51 (from the side of the reference position) toward the one side (upper side in FIG. 3) in the direction D2 (predetermined direction) and to face each other in the direction D1, and the pair of second portions 71 may be provided to extend from the central portion 51 toward the other side (lower side in FIG. 3) in the direction D2 and to face each other in the direction D1. In this case, the first extending portion 62 and the second extending portion 72 extend to intersect the Y-axis in a plan view, and do not intersect the X-axis. In this case, the pair of third portions 81 may be provided to extend from the central portion 51 toward the one side (left side in FIG. 3) in the direction D1 and to face each other with the X-axis interposed therebetween in the direction D2, and the pair of fourth portions 91 may be provided to extend from the central portion 51 toward the other side (right side in FIG. 3) in the direction D1 and to face each other with the X-axis interposed therebetween in the direction D2.

The protrusion portions 63 and 73 are not limited to being located on the X-axis and the Y-axis, and may protrude from the outer edge 31c of the body portion 31 at any locations. The protrusion portions 63 and 73 may be provided to overlap the ring-shaped portion 32 in a plan view, and may be, for example, in contact with and fixed to the ring-shaped portion 32. In this case, the rib portion 50 is connected to both the body portion 31 and the ring-shaped portion 32, so that the strength of the rib portion 50 can be improved. In the above-described embodiment, the protrusion portion 63 is provided over the entirety of the first extending portion 62 in the extending direction; however, the protrusion portion 63 may be provided only at a part of the first extending portion 62 in the extending direction. This point also applies to the protrusion portion 73 and the second extending portion 72.

The lengths L63a and L73a of the protrusion portions 63 and 73 may be less than or equal to the minimum width W5 of the first torsion bars 5 in the direction D2. The protrusion lengths L63b and L73b of the protrusion portions 63 and 73 may be more than or equal to the minimum width W5 of the first torsion bars 5 in the direction D2. The width W62 of the first extending portion 62 may be equal to the width W61 of the first portions 61 or smaller than the width W61, and the width W72 of the second extending portion 72 may be equal to the width W71 of the second portions 71 or smaller than the width W71. In a plan view, the inner edges 61a of the pair of first portions 61 may not be smoothly connected, and the inner edges 71a of the pair of second portions 71 may not be smoothly connected.

The reference position where the central portion 51 is disposed may be set at any position, and may not necessarily coincide with the center P of the body portion 31 in a plan view. The angle θ1 between the pair of first portions 61 may be equal to the angle θ3 between the pair of third portions 81 or smaller than the angle θ3. The distances T1 and T2 between the protrusion portions 63 and 73 and the ring-shaped portion 32 on the X-axis may be more than or equal to the minimum width W5 of the first torsion bars 5 in the direction D2. The body portion 31 may only be formed from at least the first semiconductor layer 101, and the rib portion 50 may only be formed from at least the second semiconductor layer 102. For example, the body portion 31 may be formed from the first semiconductor layer 101 and the insulating layer 103, and the rib portion 50 may be formed from the second semiconductor layer 102.

The drive elements of the first movable portion 3 and the second movable portion 4 are not limited to the coils 14 and 15, and may be, for example, piezoelectric elements. The coil 15 may be provided in the first movable portion 3 (for example, the ring-shaped portion 32). The motion of the first movable portion 3 may be linear motion (non-resonance motion). The second movable portion 4 and the second torsion bars 6 may be omitted. In this case, the first movable portion 3 may be directly coupled to the support portion 2 by the first torsion bars 5. In this case, the motion of the first movable portion 3 may be resonance motion or linear motion. Namely, in the above-described embodiment, the mirror device 1 includes a resonance axis and a linear axis; however, the mirror device 1 may include only one of the resonance axis and the linear axis. The first axis around which the first movable portion 3 swings and the second axis around which the second movable portion 4 swings may intersect each other at an angle other than being perpendicular, may be parallel to each other, or may be located on the same straight line. The mirror surface 10 may be configured as a diffraction grating that diffracts or reflects light. In this case, the mirror surface 10 may be formed, for example, by a metal film formed along a predetermined diffraction grating pattern. Alternatively, the mirror surface 10 may be formed by etching silicon (first semiconductor layer 101) (may be formed of a surface of the first semiconductor layer 101).

What is claimed is:

1. A mirror device comprising:
a support portion;
a movable portion including a body portion including a first surface and a second surface opposite to the first surface, a mirror surface being formed on the first surface and a rib portion being formed on the second surface; and
a coupling portion that couples the movable portion to the support portion such that the movable portion is swingable around a predetermined axis,
wherein the rib portion includes an extending portion extending along an outer edge of the body portion when viewed in a direction perpendicular to the second surface, and
the extending portion includes a protrusion portion protruding outward from the outer edge of the body portion and extending along the outer edge of the body portion when viewed in the direction perpendicular to the second surface.

2. The mirror device according to claim 1,
wherein when a direction parallel to the axis is a first direction, and a direction perpendicular to both the first direction and the direction perpendicular to the second surface is a second direction, a length of the protrusion portion along the outer edge of the body portion is larger than a minimum width of the coupling portion in the second direction.

3. The mirror device according to claim 1,
wherein when a direction parallel to the axis is a first direction, and a direction perpendicular to both the first direction and the direction perpendicular to the second surface is a second direction, a protrusion length of the protrusion portion from the outer edge of the body portion is smaller than a minimum width of the coupling portion in the second direction.

4. The mirror device according to claim 1,
wherein when viewed in the direction perpendicular to the second surface, the rib portion includes a pair of first portions extending from a side of a reference position toward one side in a predetermined direction and facing each other in a direction perpendicular to the predetermined direction, a first connecting portion connected to the pair of first portions, a pair of second portions extending from the side of the reference position toward the other side in the predetermined direction and facing each other in the direction perpendicular to the predetermined direction, and a second connecting portion connected to the pair of second portions, and
the extending portion is formed of the first connecting portion and the second connecting portion.

5. The mirror device according to claim 4,
wherein a width of the first connecting portion is wider than a width of each of the pair of first portions, and a width of the second connecting portion is wider than a width of each of the pair of second portions.

6. The mirror device according to claim 4,
wherein the pair of first portions are connected to each other on the side of the reference position, and the pair of second portions are connected to each other on the side of the reference position.

7. The mirror device according to claim 6,
wherein when viewed in the direction perpendicular to the second surface, inner edges of the pair of first portions are smoothly connected to each other, and inner edges of the pair of second portions are smoothly connected to each other.

8. The mirror device according to claim 4,
wherein the reference position coincides with a center of the body portion when viewed in the direction perpendicular to the second surface.

9. The mirror device according to claim 4,
wherein when viewed in the direction perpendicular to the second surface, the rib portion further includes a pair of third portions extending from the side of the reference position toward one side in the direction perpendicular to the predetermined direction and facing each other in the predetermined direction, and a pair of fourth portions extending from the side of the reference position toward the other side in the direction perpendicular to the predetermined direction and facing each other in the predetermined direction.

10. The mirror device according to claim 9,
wherein when viewed in the direction perpendicular to the second surface, an angle between the pair of first portions is larger than an angle between the pair of third portions.

11. The mirror device according to claim 1,
wherein the movable portion further includes a ring-shaped portion surrounding the body portion with a gap interposed between the ring-shaped portion and the body portion when viewed in the direction perpendicular to the second surface, and connected to the coupling portion, and a connection portion that connects the ring-shaped portion to the body portion, and
at least a part of the protrusion portion overlaps the gap when viewed in the direction perpendicular to the second surface.

12. The mirror device according to claim 11,
wherein the protrusion portion does not overlap the ring-shaped portion when viewed in the direction perpendicular to the second surface.

13. The mirror device according to claim 11,
wherein a part of the protrusion portion overlaps the ring-shaped portion when viewed in the direction perpendicular to the second surface.

14. The mirror device according to claim 11,
wherein the movable portion includes a pair of the connection portions,
when a direction parallel to the axis is a first direction, and a direction perpendicular to both the first direction and the direction perpendicular to the second surface is a second direction, the pair of connection portions are disposed on one side and the other side in the second direction with respect to the body portion, respectively,
the rib portion includes a pair of first portions extending from a side of a reference position toward one side in the first direction and facing each other in the second direction, a first connecting portion connected to the pair of first portions, a pair of second portions extending from the side of the reference position toward the other side in the first direction and facing each other in the second direction, and a second connecting portion connected to the pair of second portions, and
the extending portion is formed of the first connecting portion and the second connecting portion.

15. The mirror device according to claim 11,
wherein the protrusion portion protrudes outward from the outer edge of the body portion at least on the axis, and
when a direction parallel to the axis is a first direction, and a direction perpendicular to both the first direction and the direction perpendicular to the second surface is a second direction, a distance between the protrusion portion and the ring-shaped portion on the axis is smaller than a minimum width of the coupling portion in the second direction.

16. The mirror device according to claim 14,
wherein the first connecting portion and the second connecting portion extend to intersect the axis when viewed in the direction perpendicular to the second surface.

17. The mirror device according to claim 14,
wherein the rib portion further includes a pair of third portions extending from the side of the reference position toward the one side in the second direction and facing each other in the first direction, and a pair of fourth portions extending from the side of the reference position toward the other side in the second direction and facing each other in the first direction.

18. The mirror device according to claim 14,
wherein the pair of first portions are connected to each other on the side of the reference position, and the pair of second portions are connected to each other on the side of the reference position.

19. The mirror device according to claim 14,
wherein the reference position coincides with a center of the body portion when viewed in the direction perpendicular to the second surface.

20. The mirror device according to claim 1,
wherein the protrusion portion is not in contact with portions other than the body portion.

21. The mirror device according to claim 1,
wherein the support portion, the movable portion, and the coupling portion are formed by a semiconductor substrate including a first semiconductor layer, a second semiconductor layer, and an insulating layer disposed between the first semiconductor layer and the second semiconductor layer,
the body portion is formed by at least the first semiconductor layer, and
the rib portion is formed by at least the second semiconductor layer.
